(19) United States
(12) Patent Application Publication
(10) Pub. No.: US 2012/0075784 A1
(43) Pub. Date: Mar. 29, 2012

(54) DISPLAY DEVICE

(75) Inventors: Kuo-Nan Ling, Taipei City (TW); Po-An Lin, Taipei City (TW); Yung-Hui Chen, Taipei City (TW)

(73) Assignee: COMPAL ELECTRONICS, INC., Taipei City (TW)

(21) Appl. No.: 13/277,206

(22) Filed: Oct. 19, 2011

Related U.S. Application Data
(63) Continuation-in-part of application No. 13/171,482, filed on Jun. 29, 2011.
(60) Provisional application No. 61/429,189, filed on Jan. 3, 2011.
(60) Provisional application No. 61/359,811, filed on Jun. 29, 2010.

(51) Int. Cl. H05K 7/02

(52) U.S. Cl. 361/679.01

(57) ABSTRACT

A display device includes a housing, a frame, a display module, and a connecting structure. The frame is adhered in the housing, and surrounds the display module. The display module is disposed and fixed in the housing by connecting structure connecting with the frame.

### CROSS-REFERENCE TO RELATED APPLICATION

This application claims the priority benefits of U.S. provisional application Ser. No. 61/429,189, filed on Jan. 3, 2011, and also is a continuation-in-part application of and claims the priority benefit of a prior application Ser. No. 13/171,482, filed on Jun. 29, 2011, now pending. The prior application Ser. No. 13/171,482 claims the priority benefit of U.S. provisional application Ser. No. 61/359,811, filed on Jun. 29, 2010. The entirety of each of the above-mentioned patent applications is hereby incorporated by reference herein and made a part of this specification.

### BACKGROUND OF THE INVENTION

1. Field of the Invention

The invention relates to an electronic device. More particularly, the invention relates to an electronic device that is equipped with a display device.

2. Description of Related Art

Along with development of semiconductor devices and display techniques, electronic products have been continually developed toward miniaturization, multi-functionality, and portability. The common portable electronic products include notebook computers, tablet computers, mobile phones, etc. The notebook computer is, for instance, constituted by a host and a display device pivotally connected to each other. A user is allowed to close the host and the display device of the notebook computer in order for the notebook computer to be portable. When the notebook computer is to be used, the display device can be opened by pivoting the display device relative to the host to facilitate operation and to observe the display images.

The display device of the notebook computer includes a housing, a panel module, and a backlight module. The panel module and the backlight module are configured in the housing. Generally, the panel module and the backlight module are screwed and fixed to the cover of the housing. Accordingly, the housing needs to have sufficient thickness for the screwing action, and threaded holes are required to be configured at the peripheries of the panel module, which restrains the miniaturization of the display device and reduces the display area.

### SUMMARY OF THE INVENTION

In view of the above, the invention is directed to a display device that has a housing, a frame, a display module, and a connection structure. The frame is adhered to the housing, and the frame surrounds and is in physical contact with the display module. The display module is disposed in the frame and fixed into the housing by the connection structure that connects the frame.

According to an embodiment of the invention, the frame is adhered to the housing by thermal compression.

According to an embodiment of the invention, the frame and the housing are integrally formed.

According to an embodiment of the invention, the connection structure has a plurality of connection elements, the frame has a plurality of connection portions, and each of the connection elements has a through portion and a contact portion. In each of the connection elements, the through portion passes through one of the connection portions, and the contact portion is in physical contact with the display module and the frame.

According to an embodiment of the invention, the connection structure is a first fastening element that is configured on the frame, and the display module is fastened to the first fastening element.

According to an embodiment of the invention, the display module has a panel unit and a backlight unit. The backlight unit is fastened to the first fastening structure, and the panel unit is adhered to the backlight unit.

According to an embodiment of the invention, the connection structure is a front bezel that is configured at a side of the display module opposite to the housing, the frame has a second fastening element, and the front bezel is fastened to the second fastening element.

According to an embodiment of the invention, a material of the front bezel is metal.

According to an embodiment of the invention, the display module does not have a backlight unit.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic view illustrating a display device according to a first embodiment of the invention.

FIG. 2 is a three-dimensional exploded view illustrating a display device according to the first embodiment of the invention.

FIG. 3 is a schematic enlarged view illustrating a portion of the display device according to the first embodiment of the invention.

FIG. 4 is a schematic view illustrating a display device according to a second embodiment of the invention.

FIG. 5 is a schematic view illustrating a display device according to a third embodiment of the invention.

FIG. 6 is another schematic view illustrating a display device according to the third embodiment of the invention.

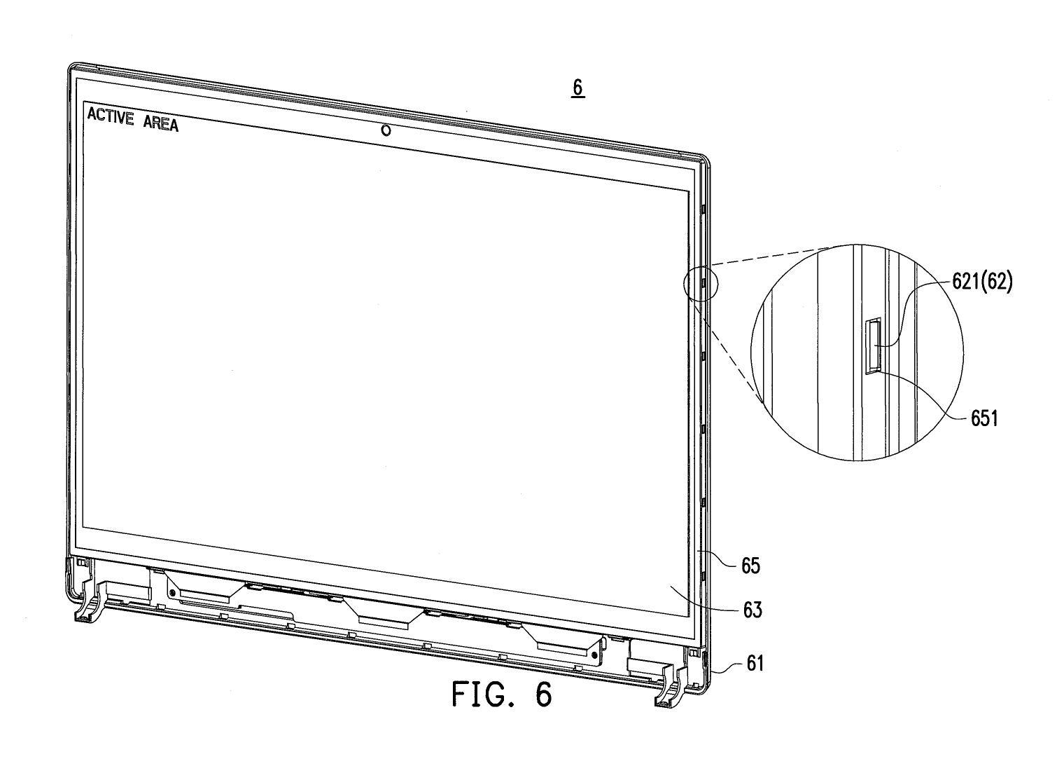

### DESCRIPTION OF EMBODIMENTS

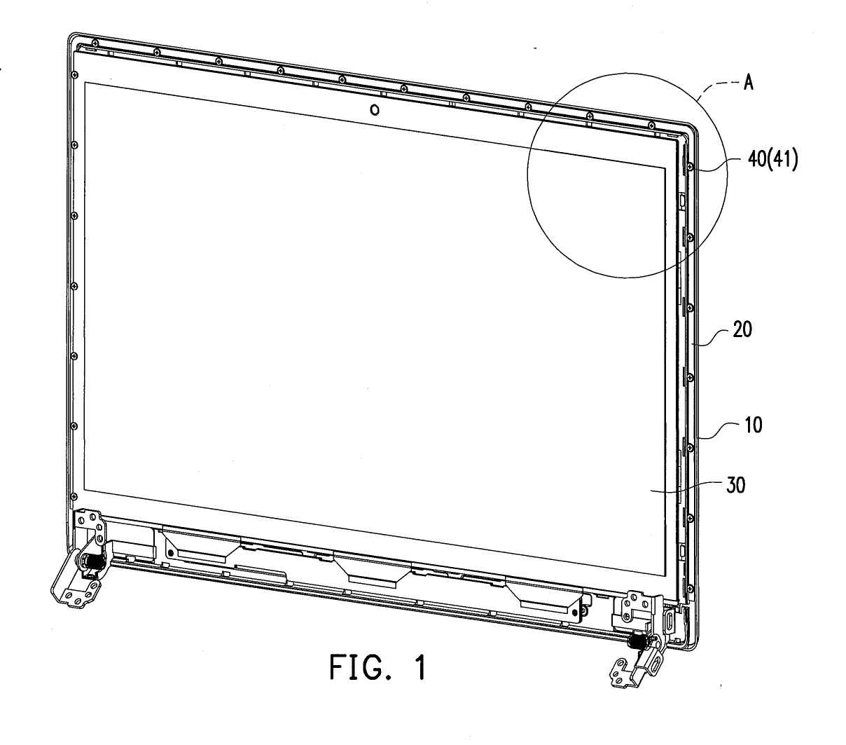

FIG. 1 is a schematic view illustrating a display device 1 according to a first embodiment of the invention. The display device 1 includes a housing 10, a frame 20, a display module 30, and a connection structure 40. In this embodiment, the display device 1 serves as the display device 1 of a notebook computer and can display images. Certainly, the display device 1 of this invention is also applicable to a tablet computer, a mobile phone, a television, and other electronic equipment.

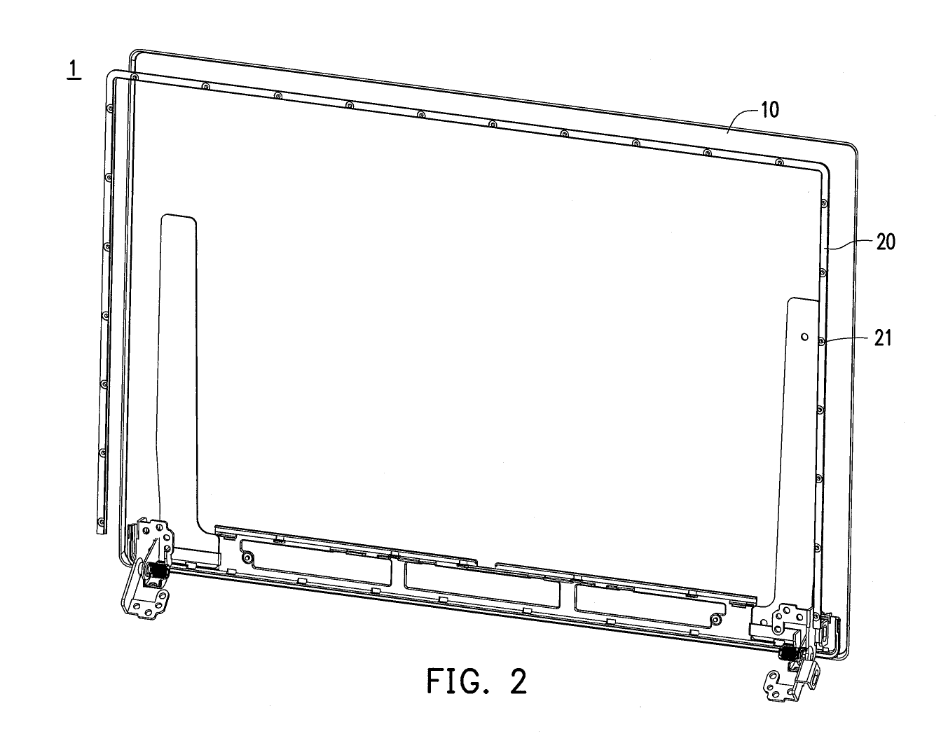

With reference to FIG. 2, in this embodiment, the frame 20 is adhered to the housing 10 by thermal compression. The frame 20 can also be attached to the housing 10 by injection molding, or the housing 10 is directly injected into a mold to form the structure of the frame 20. The frame 20 has a plurality of connection portions 21. In this embodiment, the connection portions 21 are threaded holes, for instance.

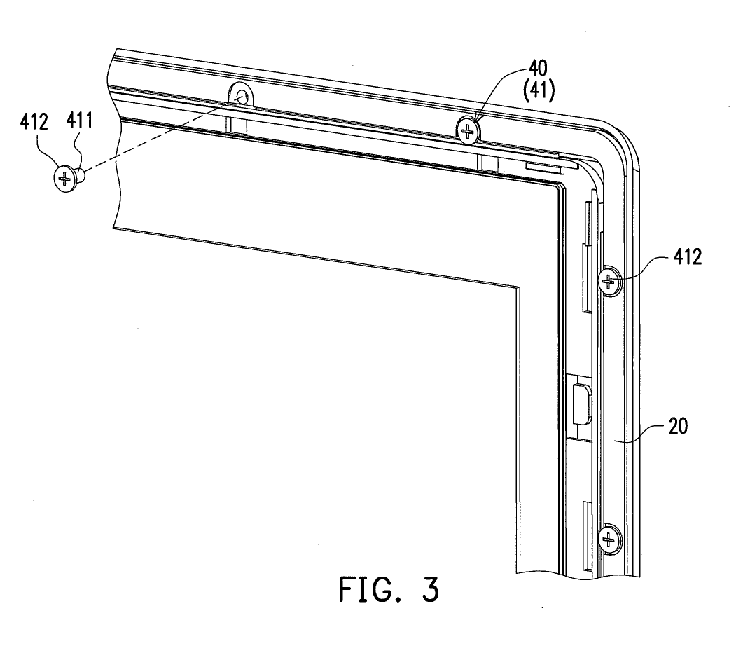

FIG. 3 is a schematic enlarged view illustrating the circle A shown in FIG. 1. The display device 1 is configured in the frame 20, and the frame 20 surrounds and is in physical contact with the display device 1. The display module 30 is fixed to the housing 10 by the connection structure 40 that connects the frame 20. The connection structure 40 has a plurality of connection elements 41. Each of the connection elements 41 has a through portion 411 and a contact portion 412. In this embodiment, the connection elements 41 are screws, the through portions 411 are threaded rods of the screws, and the contact portions 412 are heads of the screws, for instance. The connection elements 41 are fastened to each connection portion 21 of the frame 20. The contact portion 412 of each of the connection elements is in physical contact with the display module 30 and the frame 20. Thereby, the peripheries of the display module 30 are compressed by the connection elements 41, and the display module 30 can thus be fixed into the housing 10. So far, the display module 30 is completely assembled into the housing 10.

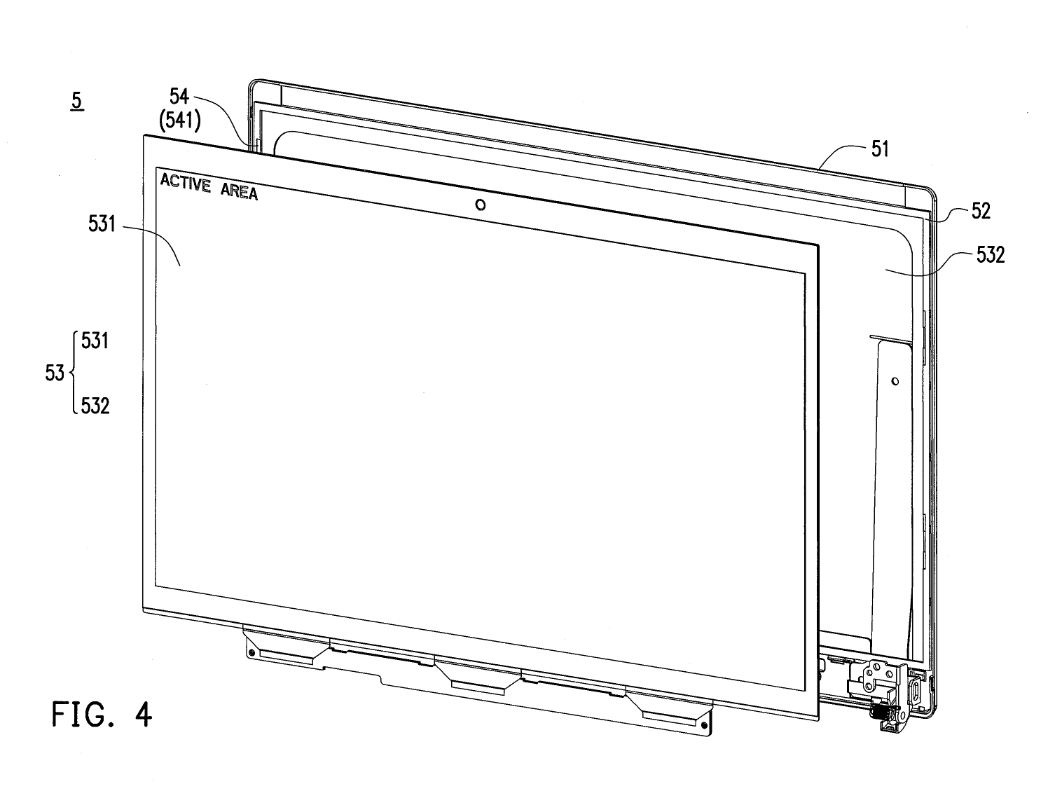

FIG. 4 illustrates a display device 5 according to a second embodiment of the invention. The display device 5 is in a liquid crystal display (LCD) and has a housing 51, a frame 52, a display module 53, and a connection structure 54. The display module 53 has a panel unit 531 and a backlight unit 532. The connection structure 54 of this embodiment is a first fastening element 541 that is configured on the frame 52. The backlight unit 532 of the display module 53 is fastened to the first fastening element 541, and the panel unit 531 is adhered to a side of the backlight unit 532. As such, the display module 53 can also be fixed into the housing 51.

However, the display device 5 described above refers to the display module 53 that is equipped with the backlight unit 532, for instance. It is likely for the display device of this invention not to be equipped with a backlight unit, e.g., an organic light-emitting diode (OLED) display device. In this case, the display module can still be fastened to the first fastening element of the frame and fixed into the housing.

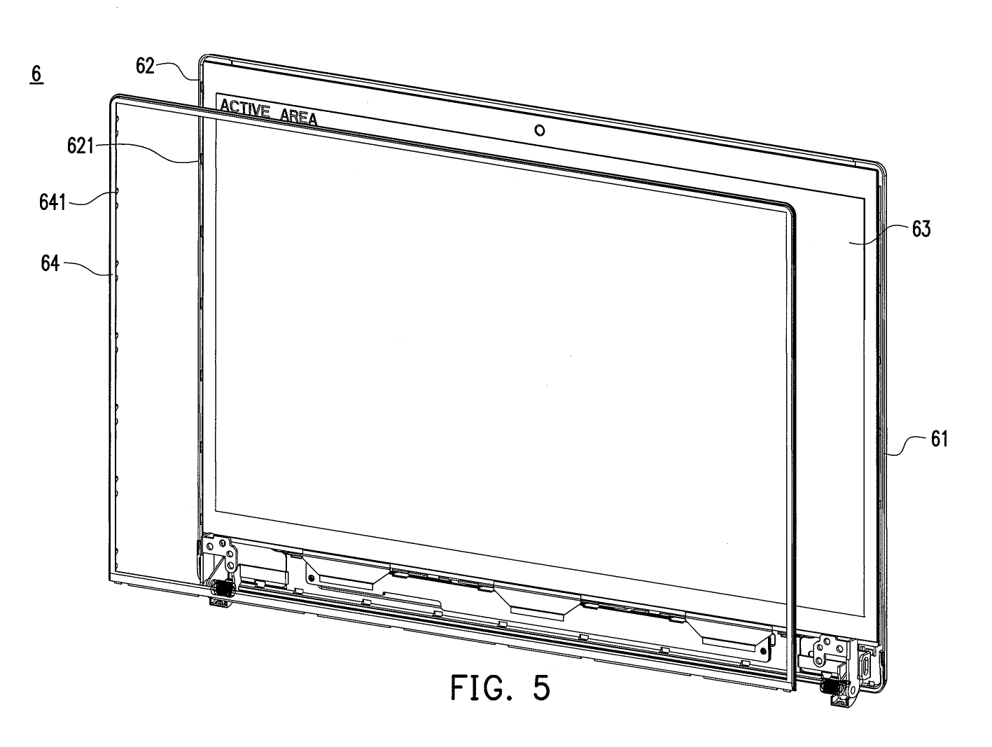

FIG. 5 is a schematic view illustrating a display device 6 according to a third embodiment of the invention. The display device 6 includes a housing 61, a frame 62, a display module 63, and a connection structure 64. The connection structure 64 in this embodiment is a front bezel that is configured at a side of the display module 63 opposite to the housing 61, and the frame 62 has a second fastening element 621. The connection structure (the front bezel) 64 is fastened to the second fastening element 621, so as to assemble the display module 63 to the housing 61. Owing to the configuration of the connection structure (the front bezel) 64, the panel unit and the backlight unit can be bonded by stacking the panel unit onto the backlight unit instead of adhering the two units. The display module 63 can thus be sandwiched between the connection structure (the front bezel) 64 and the housing 61 by fastening the connection structure (the front bezel) 64 to the second fastening element 621.

However, the connection structure (the front bezel) 64 in this embodiment is a plastic frame and has a plurality of hooks. The second fastening element 621 of the frame 62 refers to holes that can be fastened to the hooks of the connection structure (the front bezel) 64. The invention is certainly not limited thereto. As shown in FIG. 7, the connection structure (the front bezel) 65 can also be a metal frame and has a plurality of holes. The second fastening element 621 of the frame 62 refers to protrusions that can pass through the holes of the connection structure (the front bezel) 65.

Undoubtedly, the display module of this invention is fixed to the housing by the connection structure that connects the frame. Based on actual requirements, the display module can be connected to the frame by one, some, or all of the connection structures described in the first, second, and third embodiments. Thereby, the display module can be fixed into the housing. For instance, the display module can be locked to the first fastening element of the frame as described in the second embodiment of the invention, and the front bezel described in the third embodiment of the invention can be further locked to the second fastening element of the frame, such that the display module can be securely configured in the housing.

In light of the foregoing, the display module in the display device as described in the embodiments of the invention can be fixed into the housing by the connection structure that connects the frame. Here, the connection structure can refer to the connection elements, the first fastening element of the frame, or the front bezel that is locked to the second fastening element of the frame, so as to fix the display module to the housing. Moreover, due to the configuration of the frame and the connection structure, the housing itself is not equipped with any other connection structure and is indeed miniaturized.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A display device comprising:
a housing;
a frame adhered to the housing;
a display module disposed in the frame, the frame surrounding and being in physical contact with the display module; and
a connection structure, the display module being fixed into the housing by the connection structure connecting the frame.

2. The display device as recited in claim 1, wherein the frame is adhered to the housing by thermal compression.

3. The display device as recited in claim 1, wherein the frame and the housing are integrally formed.

4. The display device as recited in claim 1, wherein the connection structure has a plurality of connection elements, the frame has a plurality of connection portions, each of the connection elements has a through portion and a contact portion, in each of the connection elements, the through portion passes through one of the connection portions, and the contact portion is in physical contact with the display module and the frame.

5. The display device as recited in claim 1, wherein the connection structure is a first fastening element configured on the frame, and the display module is locked to the first fastening element.

6. The display device as recited in claim 5, wherein the display module has a panel unit and a backlight unit, the backlight unit is locked to the first fastening element, and the panel unit is adhered to the backlight unit.

7. The display device as recited in claim 1, wherein the connection structure is a front bezel configured at a side of the display module opposite to the housing, the frame has a second fastening element, and the front bezel is locked to the second fastening element.

8. The display device as recited in claim 7, wherein a material of the front bezel is metal.

9. The display device as recited in claim 1, wherein the display module does not have a backlight unit.
